(19) United States
(12) Patent Application Publication
(10) Pub. No.: US 2006/0185713 A1
(43) Pub. Date: Aug. 24, 2006

(54) Solar panels with liquid superconcentrators exhibiting wide fields of view

(76) Inventor: William J. Mook JR., Columbus, OH (US)

Correspondence Address: MUELLER AND SMITH, LPA;MUELLER-SMITH BUILDING, 7700 RIVERS EDGE DRIVE, COLUMBUS, OH, 43235, US

(21) Appl. No.: 11/063,625

(22) Filed: Feb. 23, 2005

(51) Int. Cl. H01L 31/042

(52) U.S. Cl. 136/244; 136/246

(57) ABSTRACT

Solar panel system and apparatus wherein the panels are configured with liquid superconcentrators having outwardly disposed liquid imaging lenses of wide field of view performing with a sparse array of discrete multifunction photovoltaic cells which are electrically interconnected to provide a panel output. The liquid superconsentrator and associated sparse array of photovoltaic cells are configured in a row and column matrix and are mounted upon a polymeric back support.

### CROSS-REFERENCE TO RELATED APPLICATIONS

### STATEMENT REGARDING FEDERALLY SPONSORED RESEARCH

Not applicable.

### BACKGROUND OF THE INVENTION

Solar radiation is the preponderant source of energy asserted to the earth. Some fraction of that energy will have been consumed in the photosynthetic process associated with the plant and animal kingdoms which over the earths' life has evolved as fossil fuels including, inter alia, oil, natural gas and coal. World industrialization continues to withdraw the former two resources at a rate forecasting a realistic need for an alternative source of power. That alternative source of power must utilize practical technology to supplant the exhausting oil and gas resources at realistic and currently competitive costs. The radiative energy of the sun is the logical oil-gas fossil resource-supplanting candidate.

Historically, the conversion of solar energy into electrical energy utilizing, for example, photoelectric devices has been considered to have marginal utility. Early as well as current plate-type devices are somewhat small, non-concentrating and non-suntracking. Thus their employment has been limited, for example, to remote applications carrying out the recharging of batteries. Considered on cost per watt hour basis (about $6.00 per watt to $8.00 per watt) this form of power generation is quite expensive.

In 1973, with the advent of the oil crisis, government funded efforts were undertaken to develop concentration-based photovoltaic systems as an alternate energy source. Some large scale demonstration facilities were constructed.

As the energy crisis passed and oil prices lowered, concentrator-based photovoltaic programs diminished. At the present time, while important improvements in concentrator-based photovoltaic systems have been developed, the cost of power produced by them remains non-competitive with fossil fuel-based generation. In general, the demonstration facilities involved quite large parabolic concentrators having mechanical sun tracking features combined with the elaborate heat sinking systems. An important aspect of the high costs of these systems necessarily resides in the necessary rigidity and stability of the large devices under varying environmental wind loads and temperatures. In 2000, a leading concentration-based photovoltaic investigator stated:
In reaching for the ultimate goal of providing clean, renewable energy, concentrators compete head-on with existing fossil fuel-fired generators. Projected electricity costs from concentrator power plants are about three times the current cost of energy from natural gas power plants. Early concentrator plants will be twice as expensive again. There is nothing that can be done about this without government involvement, period. We need to decide as a society if environmental issues such as acid rain, global warming, and reduced health are important enough to subsidize this difference for a while.
Richard M. Swanson, “The Promise of Concentrators”, Prog. Photovolt. Res. Appl. 8, 93-111 (2000).

Multijunction photovoltaic cells evolved in concert with the large concentration systems. When combined with the concentrators the potential increase in power produced by given solar cells of 100 to 1200-fold is realized. One multijunction cell which has been introduced is the high voltage silicon vertical multijunction solar cell. Sometimes referred to as an “edge-illumination” multijunction cell, the VMJ cell is an integrally bonded series-connected array of miniature silicon vertical junction cell units. The devices are described in U.S. Pat. Nos. 4,332,973; 4,409,422; and 4,516,314.

Another innovation in concentration photovoltaic devices is described as a point contact solar cell. To accommodate low voltage characteristics of the photovoltaic devices, multiple junctions of the small area cells are arranged in series in a monolithic semi-conductor substrate. The devices currently are referred to as “back surface point contact silicon solar cells”. Such cells and their manufacture are described in U.S. Pat. Nos. 4,927,770; 5,164,019; 6,274,402; 6,313,395; and 6,333,457.

Endeavors also have been witnessed which are concerned not only with multijunction cell design but multispectral structuring. In general, these devices utilize a combination of Periodic III-V semiconductor materials to capture an expanded range of photon energies. One concept in this regard has been to split the imagining spectrum to photovoltaicly engage semiconductor materials somewhat optimized to a split-off spectral band. An approach considered more viable has been to grow multiple layers of semiconductors with decreasing band gaps. Top layers of these devices are designed to absorb higher energy photons while transmitting lower energy photons to be absorbed by lower layers of the cell. Alloys of Group III and Group V elements, as well as other related compounds, lend themselves well to the design of multispectral-multijunction cells. Indium phosphide (InP) and gallium arsenide (GaAs) are examples of such III-V materials. For example, a Ga_{0.5}In_{0.5P} also known as GaInP₂ has been produced.

See generally, the online document by B. Burnett:
(1) www.nrel.gov\ncpv\pdfs\11_{—}20_dga_basics_{—}9-13.pdf

Drawbacks heretofore associated with concentration photovoltaic systems reside in the heat which is built-up in them occasioned by their relatively lower efficiencies. That heat is the result of ineffective photonic interaction with the cells, i.e., only a portion of the concentrated solar energy is converted at their depletion layers into useful energy, the rest being absorbed as heat throughout the cell. Compounding this difficulty, the cells must be operated under restrictive temperature limits. While heat sinking is utilized to combat heat build-up, there are limits to heat sinking capabilities.

W. H. Mook, in application for U.S. patent Ser. No. 10/656,710 entitled “Solar Based Electrical Energy Generation With Spectral Cooling”, filed Sep. 5, 2003 describes a significant improvement in output performance for multijunction and multispectral photovoltaic cells with a technique which recognizes that each form of photovoltaic material exhibits a unique wavelength defined bandgap energy and further associates that bandgap energy characteristic with a unique wavelength defined band of useful photon energy. Within that band of useful photon energy a substantial amount of efficient photon-depletion layer interaction is achieved. In general, that useful band extends rearwardly or toward shorter wavelengths to about one-half of the value of the wavelength at bandgap energy. By removing wavelengths above and below the band of useful wavelengths, ineffective solar energy components (ISEC) are substantially eliminated with their attendant heat generating attributes. As a consequence, substantially more beneficial use may be made of heat sinking practices associated with the series-connected arrays of photovoltaic cells to the extent that greater solar concentrations are realized with concomitantly more efficient electrical energy generation.

With this spectral cooling improvement, consideration of solar power production practicality now must address the cost and awkwardness of the concentrator systems. The large and elaborate tracking mirror structures heretofore employed are cost prohibitive. Further, because solar radiation is available only on intermittent basis, practical and cost effective electrical energy generation, use and transmission systems are called for.

### BRIEF SUMMARY OF THE INVENTION

The present invention is directed to a system and apparatus deriving an electrical output from radiation of the sun. Such electrical output derivation is achievable at cost levels generally below those associated with conventional fossil fuel-based generation systems.

The system utilizes arrays of thin, rectangular interconnected panels, the components of which are formed of thermoplastic resin, a liquid such as water, a sparse photovoltaic cell array, and electrical interconnections. The panel arrays are disposed in stationary fashion upon ground surface such as reclaimed surface mine terrain as well as so-called “brown fields”. In general, each panel exhibits a length of about 8 feet and a width of about 4 feet. When combined in paired panel arrays of about 550 panels each, a linear array length of about one mile between d.c. collecting facilities is developed. Panel arrays covering thousands of square miles of terrain are contemplated.

Each panel is formed with an array of quite thin liquid-filled thermoplastic resin shells or surfaces, each configured with an outwardly disposed liquid imaging lens or primary concentrator of hemispherical or fish-eye shape. The acceptance angle and associated field of view of these hemispherical lenses is engineered to be quite wide. In this regard, in an initial embodiment a field of view of about 120° is realized. That wide field of view is sufficient to image the sky and sun throughout about an eight hour day. A more optically sophisticated liquid imaging lens is disclosed which is engineered to exhibit a field of view of about 240°. Thus, no expensive, necessarily rigid and tolerance mandating large sun tracking parabolic mirrors are involved with the panel-based system of the invention.

Each imaging lens is optically joined with a liquid, non-imaging, internally reflecting secondary concentrator, again formed as a liquid-filled thermoplastic resin thin shell or surface which further concentrates radiation from the imaging lens and directs it as homogenized radiation to an exit plane. The active area or receiving surface of a small multijunction photovoltaic shell is supported in the concentration liquid at that exit plane. For the embodiment disclosed, a hemispherical imaging lens exit plane exhibits an area of 645 square millimeters, while the photovoltaic cell active area is 2.25 millimeters squared to provide a geometric concentration ratio of about 286.7:1.

The liquid secondary concentrator basically comprises a logarithmetic concentrator having an entrance configured and located for receiving radiation at the image plane of the imaging lens and has one or more surfaces extending from the entrance logarithmetically approaching the axis of the optical cell to an exit. A compound parabolic concentrator having one or more surfaces located for receiving radiation from the logarithmetic concentrator exit also is provided which functions to concentrate homogenized radiation at the noted exit plane where the photovoltaic cell active area is located. In the principal embodiment disclosed, a conical concentrator having an entrance adjacent the imaging lens exit and an exit adjacent the image plane is provided having one or more side surfaces inclined toward the cell axis. The combination of the wide-angle imaging lens with the non-imagining internally reflecting secondary concentrator structure is generally referred to as a “superconcentrator”.

The currently preferred thermoplastic resin from which the thin clear shells of the optical cells are formed is a polyester resin such as polyethylene terephthalate (PET).

A panel dimensioned as having a length of about 8 feet and a width of about 4 feet will contain an array of the liquid superconcentrators and associated multijunction photovoltaic cells which are formed generally in a matrix of rows and columns, the rows being designated as parallel with the 8 foot length and the columns being designated as generally parallel with the 4 foot width. Such an arrangement of the superconcentrator cells and photovoltaic cells united therewith will provide 48 rows of 96 serially interconnected photovoltaic cells. The ends of these rows then are electrically parallel coupled together to provide panel outputs.

The liquid superconcentrators are filled with a pure water which is associated in thermal exchange relationship with the coupled photovoltaic cell active area to promote cooling. Cooling also is achieved by implementing the above-described spectral cooling. In this regard, one or more dyes or bandwidth absorbing additives effective to absorb solar energy from at least a portion of those wavelengths substantially ineffective to evoke a photovoltaic output may be provided. Additionally, the water may include one or more wavelength shifting additives which are effective to shift at least a portion of ineffective solar energy components to one or more bandwidths effective to evoke a photovoltaic output. With this shifting approach, not only is spectral cooling achieved but the efficiency of the system is enhanced by producing radiation at effective wavelengths.

The arrays of superconcentrators may be configured exhibiting not only circular cross-sections but also regular polygon cross-sections through the utilization of plano surfaces. For example, the cross-sections evolved may be square as noted above, triangular or hexagonal.

The photovoltaic cells and associated superconcentrator liquid lenses are mounted upon a back support which is comprised of a polymeric lattice supporting the rows of photovoltaic cells and associated series coupled electrical interconnections as well as an outer frame. That frame may be formed with oppositely disposed mounting flanges adjacent the 4 foot widths which are bendable downwardly in the field to facilitate the field installation of arrays of panels. One flanged side also may be configured to provide deployable downwardly depending polymeric legs to develop a desired slope for rainwater runoff.

Other objects of the invention will, in part, be obvious and will, in part, appear hereinafter.

The invention, accordingly, comprises the system and apparatus possessing the construction, combination of elements and arrangement of parts which are exemplified in the following detailed description.

For a fuller understanding of the nature and objects of the invention, reference should be made to the following detailed description taken in connection with the accompanying drawings.

### BRIEF DESCRIPTION OF THE DRAWINGS

FIG. 1 is a top view of a solar radiation responsive panel configured according to the invention;

FIG. 2 is a side view of the panel of FIG. 1;

FIG. 3 is an enlarged partial view of a portion of the panel of FIG. 1;

FIG. 4 is a side view of the panel of FIG. 3;

FIG. 5 is a perspective view of a portion of the panel structure of FIG. 1;

FIG. 6 is an exploded perspective view of the panel components shown in FIG. 5;

FIG. 7 is a partial perspective view of imaging lens shell-defined cavities shown in FIG. 6;

FIG. 8 is a partial perspective view of concentration component shells shown in FIG. 6;

FIG. 9 is a perspective view of an optical cell and associated lattice-mounted photovoltaic cell shown in FIG. 5;

FIG. 10 is a sectional view taken through the plane 10-10 in FIG. 9;

FIG. 11 is a schematic representation of hemispherically-shaped imaging lenses showing the effect of low angle radiation on such an arrangement;

FIG. 12 is a perspective view of an optical cell according to the invention exhibiting a circular cross-section;

FIG. 13 is a schematic representation of one matrix array of imaging lenses exhibiting a circular cross-section;

FIG. 14 is a schematic view of another array matrix of imaging lenses exhibiting a circular cross-section;

FIG. 15 is a schematic view of an array of imagining lenses exhibiting a triangular cross-section;

FIG. 16 is a schematic view of an array of imaging lenses exhibiting a hexagonal cross-section;

FIG. 17 is a schematic view of an array of imaging lenses exhibiting a square cross-section but rotated 45° with respect to a panel edge;

FIG. 18 is a top broken view of a panel back support supporting an array of photovoltaic cells;

FIG. 19 is an exploded perspective view of a portion of the back support and photovoltaic cell array of FIG. 18;

FIG. 20 is a sectional view taken through the plane 20-20 in FIG. 18;

FIG. 21 is a schematic Planck curve showing bandgap energy locations for a multifunction silicon photovoltaic cell and illustrating a useful wavelength band for spectral cooling;

FIG. 22 is a schematic Planck curve for a multi-spectral mujltijunction photovoltaic cell;

FIG. 23 is a perspective representation of a superconcentrator optical cell showing discrete lens components and concentrators as they are spatially arranged;

FIG. 24 is a slightly exploded sectional view of an optical cell as at FIG. 23 showing its configuration for retaining liquid within the discrete cell components utilizing thin polymeric sheets;

FIG. 25 is a perspective view of a sequence of solar panels according to the invention schematically illustrating their electrical and physical interconnection;

FIG. 26 is a side view of panels shown in FIG. 25 being Z-folded for shipment;

FIG. 27 is a side view of a truck trailer upon which folded panels are positioned for transportation to a power generating site;

FIG. 28 is a top view of panel arrays at an energy production site;

FIG. 29 is a sectional view taken through the plane 29-29 in FIG. 28;

FIG. 30 is a sectional view similar to FIG. 29 but showing panel installations upon sloping ground surface; and

FIG. 31 is a sectional view similar to FIG. 29 but showing panels according to the invention mounted upon the ground surfaces of sloping terraces.

### DETAILED DESCRIPTION OF THE INVENTION

In the discourse to follow the general structure of each panel of the conversion system as it is developed during manufacture is described, whereupon the array of liquid-filled superconcentrator components is set forth. Next, the generally rectangular back support with its lattice form of construction and frame is addressed. The superconcentrator optical cells may be arranged in a variety of matrixes and such variations in the arrays with respect to the cross-sectional shape of the optical elements are discussed. The optical elements further employ the spectral cooling features described in application for U.S. patent Ser. No. 10/656,710 (supra). That feature is revisited in conjunction with two Planck curves, whereupon the practical interconnection and transportation of the relatively light panels is discussed along with an illustration of linear panel arrays which may combine to have a length, for example, of about one mile when installed on terrain. Various terrain installations are then addressed. Also, a more sophisticated liquid filled optical cell is disclosed.

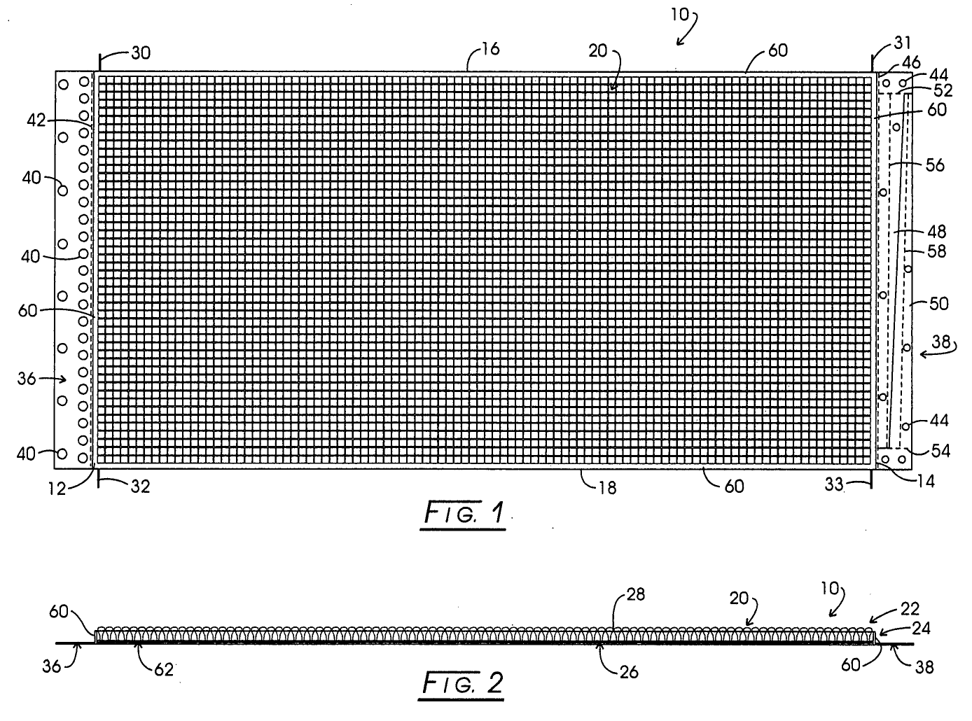

Referring to FIG. 1, a sun radiation based electrical energy generating panel is represented generally at 10. Panel 10 is rectangular in peripheral configuration having oppositely disposed end of peripheries 12 and 16. Those end peripheries have a length of about four feet. Extending between the end peripheries 12 and 14 are oppositely disposed lengthwise sides 16 and 18 having a length of about eight feet. Panel 10 is intended for stationary mounting in a panel array on terrain and basically is configured with an array of a superconcentrator form of optical cells, each of which is formed with an imaging spherical lens component or primary concentrator. That imaging component preferably is formed with an uppermost hemispherical imaging lens having an engineered acceptance angle or field of view. Thus, each of the optical cells is capable of tracking sun radiation throughout a substantial portion of a sun day. In this regard, in a principal embodiment, the field of view of the spherical lens is about 120° generally providing for sun radiation acceptance throughout an interval of eight daylight hours. The optical cells are represented in general at 20. Looking additionally to FIG. 2 it may be seen that the cells exhibit an upwardly disposed hemispherical imaging lens array as represented at 22. However, while these imaging lenses are hemispherical (fish-eye) they are configured with planer peripheral sides of square cross-section which are evident in FIG. 1. FIG. 2 further reveals that the imaging lenses 22 are associated with a secondary concentrator array as represented in general at 24. Each of the secondary concentrators is formed of one or more non-imaging internally reflecting concentrator components which receive radiation from an associated imaging lens, effect homogenization of that radiation and concentrate it to an exit plane (not shown) at which a very small photovoltaic cell is positioned. Arrays 22 and 24 are each formed from a single sheet of clear polyester resin having a thickness of between about 150 to about 200 microns. For the instant demonstration, the imaging lenses exhibit a square cross-sectional lower portion of about 645 square millimeters at their exit areas. Each of the secondary concentrator components is generally horn-shaped and extends to an exit plane which, in turn, directs concentrated, homogenized light to the active receiving surface area of discrete photovoltaic cells. For example, that active area will have a square periphery of about 1.5 millimeters on a side to provide an area of 2.25 square millimeters. The array of photovoltaic cells along with the circuit components of a collection network are mounted upon a generally rectangular back support seen in FIG. 2 at 26. Imaging lens array 22 and concentrator array 24 are formed from single sheets of a polyester resin such as polyethylene terephthalate which are sealed together, for example, by ultrasonic welding as represented at the seal line 28 and are filled with a liquid such as a somewhat pure water which may be under slight pressure.

Returning to FIG. 1, the combined array of optical cells and correspondingly sparse array of photovoltaic cells may be considered to be arranged in a matrix of rows parallel to lengthwise sides 16 and 18 and columns parallel to end peripheries 12 and 14. Each row will contain about 96 cells which are coupled together in series circuit fashion between end peripheries 12 and 14. There are about 48 of these rows which extend to the end peripheries 12 and 14 at which location the serially coupled photovoltaic cells constituting each row are connected electrically in parallel to provide panel outputs at the lengthwise sides 16 and 18 at a location in adjacency with end peripheries 12 and 14. For example, panel outputs 30 and 31 extend from lengthwise side 16, while panel outputs 32 and 33 extend from lengthwise side 18.

With the arrangement shown, each photovoltaic cell will exhibit a nominal voltage output of about 28 volts which are series combined within each designated row.

The instant figures further reveal that the panel back support 26 (FIG. 2) includes a frame portion 62 which is configured having oppositely disposed inwardly bendable ground engaging flanges represented in general at 36 and 38. Flange 36 is configured with open apertures or through-holes certain of which are identified at 40 and is bendable downwardly as represented by the dashed bend line 42. With this arrangement, when the panels as at 10 are positioned on the ground or terrain, flanges as at 36 may be bent downwardly and essentially buried in dirt. In this regard, the holes 40 function to receive components of that dirt to improve the anchoring capability of the flange.

Flange 38 similarly is configured with open apertures or holes certain of which are identified at 44 and may be bent downwardly along a bend line 46. However, the flange 38 is formed with optionally deployable ground engageable legs 48 and 50. Leg 48 is downwardly bendable at bend line 52 while leg 50 is bendable along bend line 54. To enhance the structural rigidity of legs 48 and 50, they, in turn, may be bent about respective bend lines 56 and 58 once deployed to define an angle cross-section. FIGS. 1 and 2 further reveal that the seal line or seal portion 28 is fixed to and supported from an upstanding polymeric wall 60 of rectangular configuration representing a portion of frame 62.

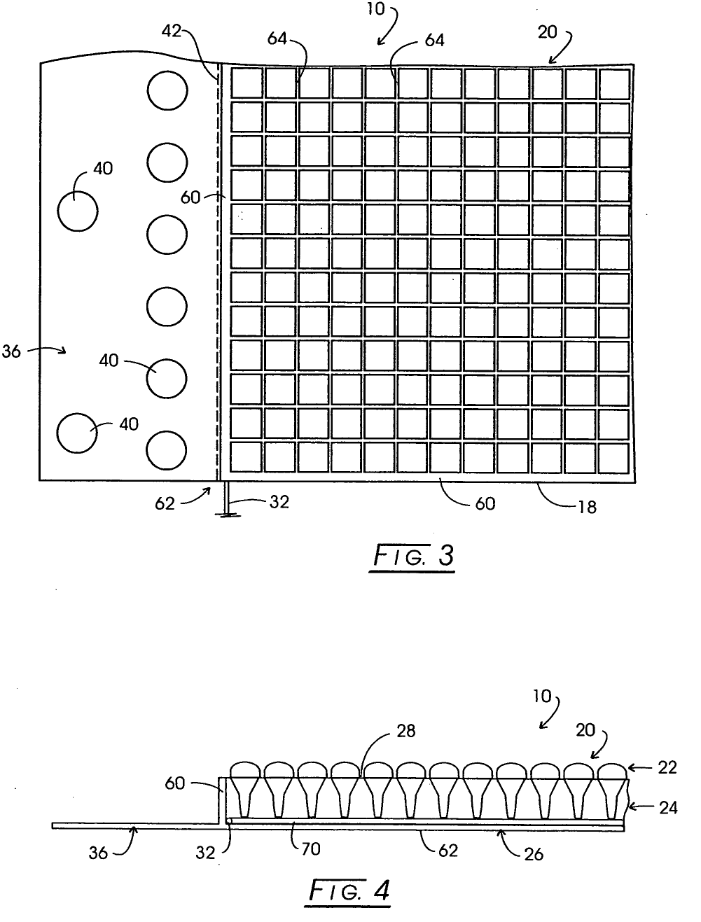

Looking to FIGS. 3 and 4, enlarged partial views of panel 10 are presented. FIG. 3 reveals that the individual hemispherical imaging lenses with plano lower side surfaces defining a square lens cross-section are slightly spaced apart by sealing flanges which ultimately form a portion of the seal line described at 28. Certain of those sealing flanges are identified at 64. FIG. 4 reveals that the back support 26 is configured with two components which are fixed together which include frame 62 and a polymeric lattice 70. Lattice 70 and frame 62 may be formed of a polyester resin such as the noted polyethylene terephthalate. FIG. 4 also reveals that the horn or concentrator components described at array 24 are each individually spaced apart in consonance with the spacing of the imaging lenses of array 22. Turning to FIG. 5, this spacing becomes apparent with the perspective rendition of a portion of panel 10. Here the array of imaging lenses 22 is revealed with the apparent spacing between adjacent piano portions of those otherwise hemispherical lenses. The secondary concentrator components at array 24 are seen to exhibit a generally horn-shape profile and exhibit cross-sections which are square in consonance with the square exit planes of the imaging lenses at array 22. Note that the horn-like components at array 24 decrease in area extent rather substantially as they reach correspondingly square photovoltaic cells supported at the lattice 70 of back support 26. The lattice row and column structuring of that back support lattice 70 becomes apparent in the figure. Note that the lattice 70 structuring exhibits a row and column defined matrix which corresponds in off-set fashion with the row and column defined matrix represented at the exit planes of the imaging lenses at array 22.

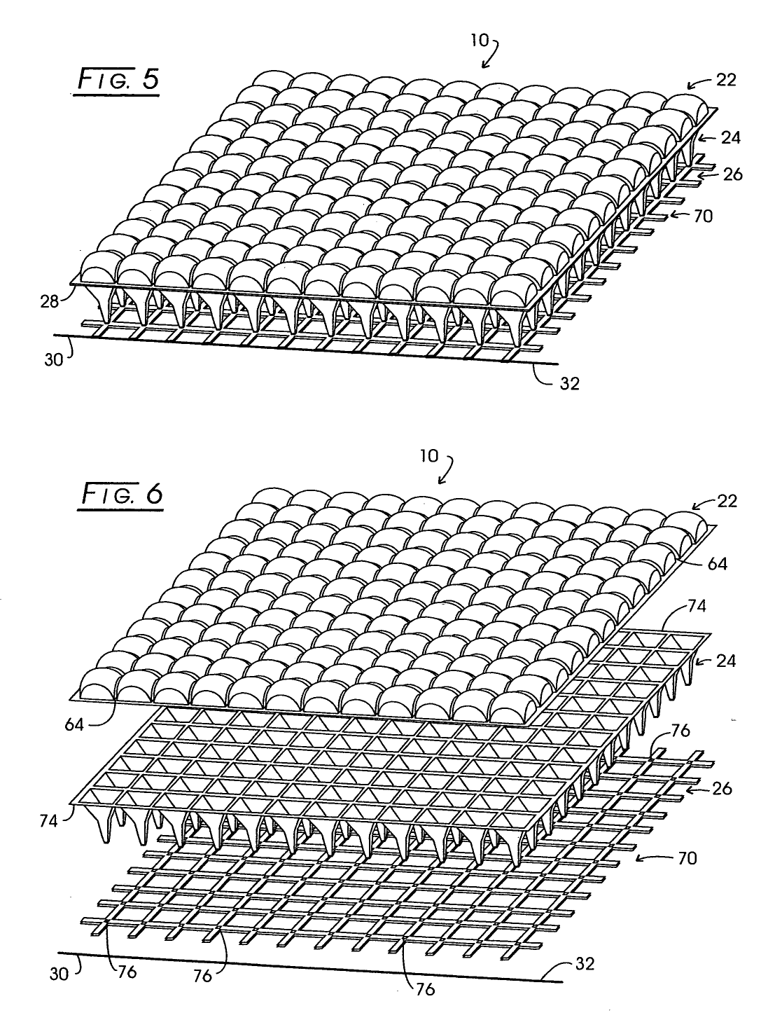

The exploded view of FIG. 6 again reveals the sealing flange 64 of imaging lens array 22. Additionally shown in the figure is a corresponding sealing flange arrangement 74 associated with the array of secondary concentrators 24. During assembly, sealing flanges 62 and 74 are ultrasonically welded together to establish seal line 28 and to define an optical cell which has a common internal cavity which is surmounted by a clear, very thin polyester resin shell or polymeric surface. The horn-like secondary concentrator components of the secondary concentrator array 24 extend in general to adjacency with an exit plane where radiation concentrated and homogenized by total internal reflection is transmissible. That transmission is to square photovoltaic cells which are supported in the noted sparse array at the lattice structured back support which is configured to retain the photovoltaic cells at square open windows certain of which are revealed at 76. Those windows are weldably attached with the open tips of the horn-shaped secondary concentrators at array 24. When the panel 10 is assembled, the common cavity represented by the imaging lenses at array 22 and the horn-shaped cavities of the secondary concentrator array 24 will have been filled with a liquid which may be provided, for instance, as a pure form of water. In addition to substantially defining the refractive index of the superconcentrators the water is in communication with the active surface of photocells within the windows 76 to enhance cooling supplementing spectral cooling. When formed with water, the superconcentrators thus formed as shown in FIG. 5 exhibit a height of about 2¾ inches, while the entire panel exhibits a thickness of about 3 inches. With the noted water filled cavities the 8 foot times 4 foot panel will weigh about 33 pounds. With the addition of the frame 62 and panel output cable, panel weight generally remains under about 40 pounds.

The very thin thermoplastic polyester resins such as polybutylene terephthalate (PBT) and polyethylene terephthalate (PET) have the highly desirable properties of exhibiting extreme low water absorption; exceptional dimensional stability due to the low water absorption; excellent resistance to chemical attack and high environmental stress crack resistance; very good heat and heat aging resistance; very low creep, even at elevated temperatures; very good colour stability; and excellent wear properties. In general, the material exhibits excellent tensil strength permitting the lens surface confined water to be under a slight pressure and the lens structures will remain intact even though the water within them may freeze. The material is conventionally used, for instance, in conjunction with bottles carrying carbonated beverages. Physical properties of these materials are described as follows:
Tensil Strength 2.5 N/mm²
Notched Impact Strength 1.5-3.5 Kj/mm²
Thermal Coefficient of Expansion 70×10⁻⁶
Maximum Continuous Use Temperature 70° C.
Density 1.37 g/cm³

Referring to FIG. 7 an enlarged partial perspective view of the imaging lens array 22 is presented. In effect, the discrete imaging lenses are fish-eye or hemispherical lenses which are truncated by four piano side surfaces certain of which are shown at 78. Those side surfaces extend outwardly from the sealing flange 62 and define a square cross-section peripheral surface which extends to an exit plane essentially at the sealing flange 62. With the arrangement shown, the piano surfaces 78 extend only a portion of the thickness of the lenses defined by a central cell axis.

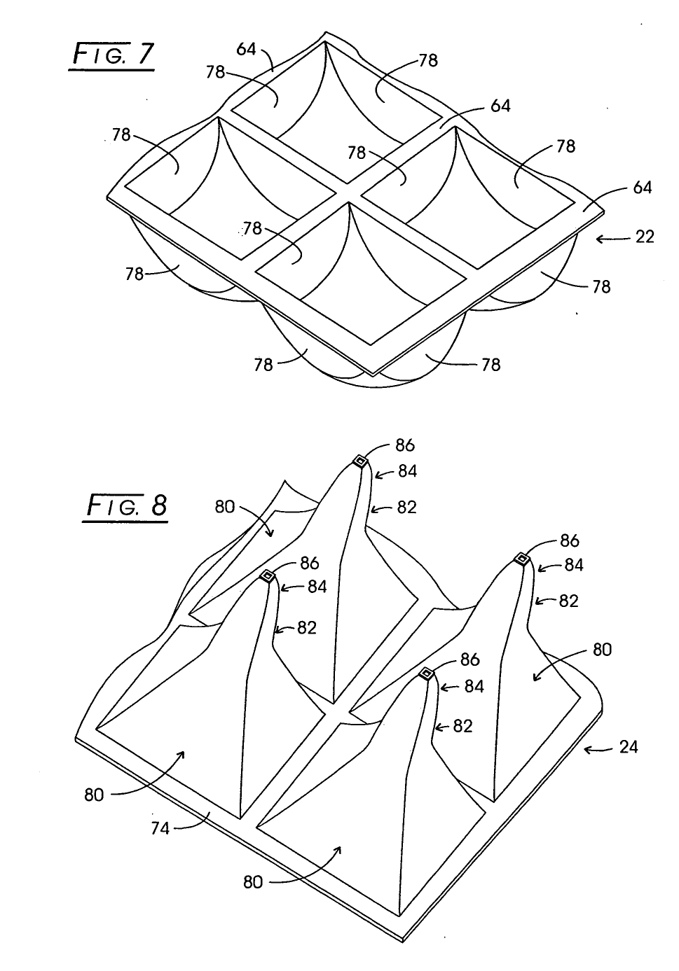

Referring to FIG. 8 an enlarged partial perspective view of the secondary concentrator array 24 is provided. Each of the secondary concentrators will be seen to be formed, inter alia, with what is referred to as a “conical concentrator” here having four piano sides represented generally at conical concentrators 80. The four piano surfaces will exhibit a square entrance which will be located adjacent the correspondingly square exit plane of an imaging lens. Each conical concentrator carries out a total internal reflection of solar radiation reaching it and directs that radiation to an exit which is adjacent the image plane of the spherical imaging lenses above it. The secondary concentrator transitions from that exit into a the entrance of a logarithmic concentrator represented generally at 82. Concentrator 82 also is totally internally reflecting and functions both to homogenize and concentrate radiation passing through it to an exit. Next, from that exit the secondary concentrator transitions to a compound parabolic concentrator represented generally at 84. Compound parabolic concentrators 84 also exhibit square cross-sections and function to concentrate radiation at an exit plane located just below an accurately formed sealing flange defined open window 86 dimensioned to correspond with the windows described at 76 in FIG. 6 formed within the back support 26 lattice 70. Such sealing windows are shown in FIG. 8 in general at 86. With the arrangement shown, the liquid such as water within the secondary concentrators 24 is in communication with the active area of each photovoltaic cell. This, as noted above, promotes a temperature controlling thermal exchange. In general, the volume of water and size of the photocell active areas are established to provide an operating temperature for each optical cell and photovoltaic cell of from between about 100° C. and 125° C. In general, the polyester resin imaging lens shells or surface and concentrator shells are blow molded or vacuum formed. It is important that the sealing windows 86 be very accurately formed to assure appropriate photovoltaic cell alignment. In general, the components 86 may be formed in conjunction with blow molding through an injection molding supplementary procedure such as is used, for example, in forming the neck portions of thermoplastic material bottles having external threads for receiving a cap. Referring to FIG. 9, an isolated and enlarged perspective view of a superconcentrator combined with a lattice supported photovoltaic cell is presented. The truncated fish-eye lens again is revealed as a hemispherical dome exhibiting a relatively broad field of view of about 120° and is configured extending along its piano sides and square cross-section to an imaging lens exit area. That exit area is met by the square cross-section of a conical concentrator which functions, in effect, as a spacer but also is totally internally reflective, i.e., no light can leave the concentrator. The logarithmic concentrator and compound parabolic concentrator again are identified respectively at 82 and 84, the latter concentrator extending to a photovoltaic cell mounted within the support lattice of back support 26.

Looking to FIG. 10, a sectional view of the assembly of FIG. 9 is presented. The figure reveals that the optical cell is disposed symmetrically about a cell axis 90. A hemispheric dome contour is illustrated at 92. The piano sides and square cross-section again are represented at 78 and extend to the imaging lens exit plane or area represented at line 94. By combining this fish-eye imaging lens with a non-imaging concentrator assembly, a superconcentrator is developed. The hemispherical water lens 92 focuses an image of the sky as represented by a 120° field of view and provides it at a small image plane represented at dashed line 96. Such focusing takes place through the total internally reflecting conical concentrator 80, two of the angularly oriented piano sides of which are revealed at 98 and 100. Such total internal reflection is in consequence of the second law of refraction, sometimes referred to as Snell's law. Here a conical water concentrator having an index of refraction of 1.334 with respect to air is developed. Accordingly, for light within the concentrator 80, angles of incidence will always be greater than the critical angle such that total reflection takes place for light within the medium of higher optical density (water) at a surface of contact with a medium of lower optical density, i.e., air. The image at image plane 96 is directed to a non-imaging internally reflecting concentrator assembly comprised of logarithmic concentrator 92 having an entrance at the image plane 96 and logarithmically converging toward cell axis 90 until reaching a logarithmic concentrator exit represented at dashed line 102. By virtue of substantial internal reflection the solar radiation is homogenized at concentrator 82, i.e., a Lambertion distribution is developed. From exit 102 the radiation is directed into a compound parabolic concentrator 84 whereupon the radiation further is concentrated to an exit plane coincident with the upwardly disposed active area surface of an associated photovoltaic cell here shown in section at 104 mounted within the support lattice of back support 26. Note that the window 76 above photovoltaic cell 104 is aligned with the sealing window 86 at the bottom of compound parabolic concentrator 84. Embedded within the back support 26 are two copper foil implemented circuit components 106 of the collection network associated with a panel. As described above, these electrically conductive foil components serially interconnect the photovoltaic cells of a given row of panel 10. Additionally revealed in the figure is the thermal transfer association of water within the optical cell and the active area of the photovoltaic cell 104.

Non-imaging concentrators were first used for detecting Cerenkov radiation in fission reactors in the 1960s. In this regard, Hinterberger and Winston of Fermilab and the University of Chicago produced non-imaging concentrators at Argon National Laboratory for the purpose of detecting such radiation. The non-imaging concentrators permit the concentration of low-density solar radiation without resort to a sun tracking mechanism.

By combining an imaging optical system with the non-imaging concentrator systems super-high concentrations may be achieved, thus as noted above, the devices have been termed “superconcentrators”.

For further discussion of the compound parabolic concentrator, see the following publication:
(2) R. Leutz and A. Suzuki, “Nonimaging Optics”, Chapter 2, Springer Verlag, Amsterdam, Nebr., 2001

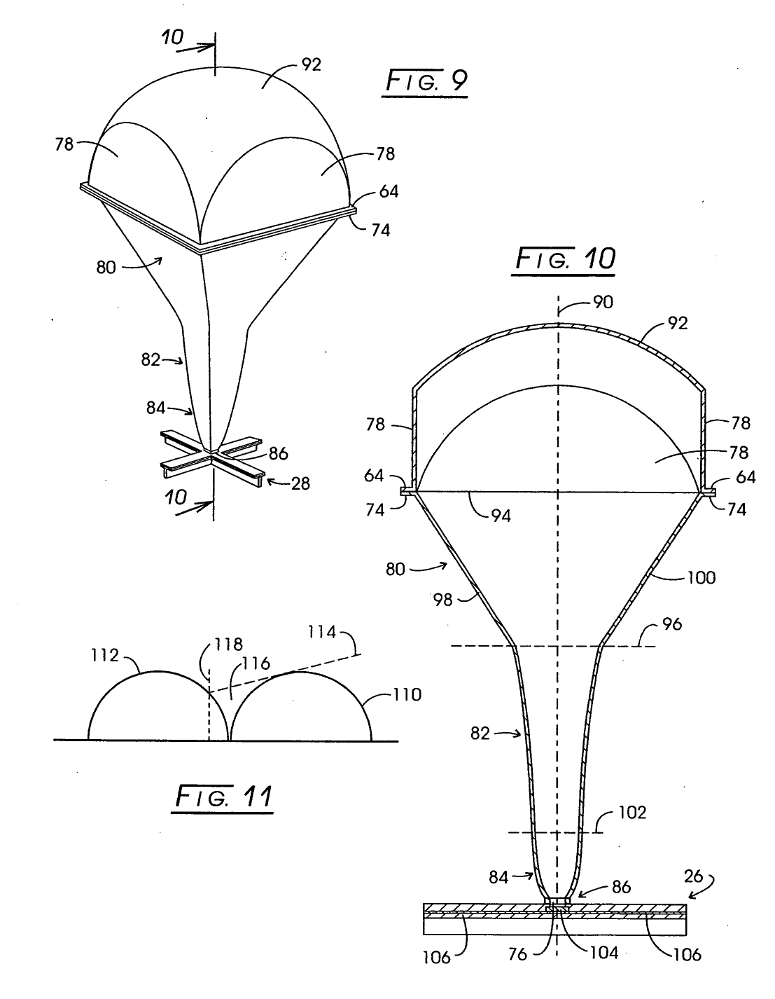

Plano components as at 78 are utilized with the imaging lenses of the optical cells both for purposes of achieving dense packing and for the purpose of eliminating shading or otherwise lost light if purely hemispherical lenses were deployed. That lost light is occasioned by radiation when at a relatively low angle of attack. Looking to FIG. 11, adjacently disposed hemispherical lenses 110 and 112 are depicted in profile. A light ray with a low angle of attack is represented at dashed line 114. Note that low angle radiation will, in effect, cause hemispherical lens 110 to shade portions of hemispherical lens 112 as represented at the shade region 116. By truncating these hemispheric imaging lenses with piano sides as represented at dashed line 118 the shaded area 116 is eliminated and closer packing may be achieved. In general, these truncating peripheral surfaces will be parallel with the cell axis as at 90 and extend from the exit plane 94 a distance less than the thickness of the lens. With respect to such thickness, it is considered the distance from the peak of hemispherical surface 92 to the exit plane 94. The optical cell arrays may be molded with common piano surfaces 78 between adjacent cells. Such an arrangement will provide a strengthening and permit denser cell packing. However, optical cells with circular cross-sections are contemplated with the instant invention. Such an optical cell is represented in general at 130 in FIG. 12. Looking to that figure, a hemispherical fish-eye lens is represented at 132 disposed symmetrically about cell axis 134. Lens 132 extends to an annulus-shaped sealing flange 136. Flange 136 is, in turn, sealed to sealing flange 138 at the entrance to a conical concentrator represented generally at 140 which also exhibits a circular cross-section. Conical concentrator 140 also is symmetrically disposed about cell axis 134 and extends to a logarithmic concentrator represented generally at 142. Concentrator 142, in turn, smoothly transitions to a compound parabolic concentrator represented generally at 144.

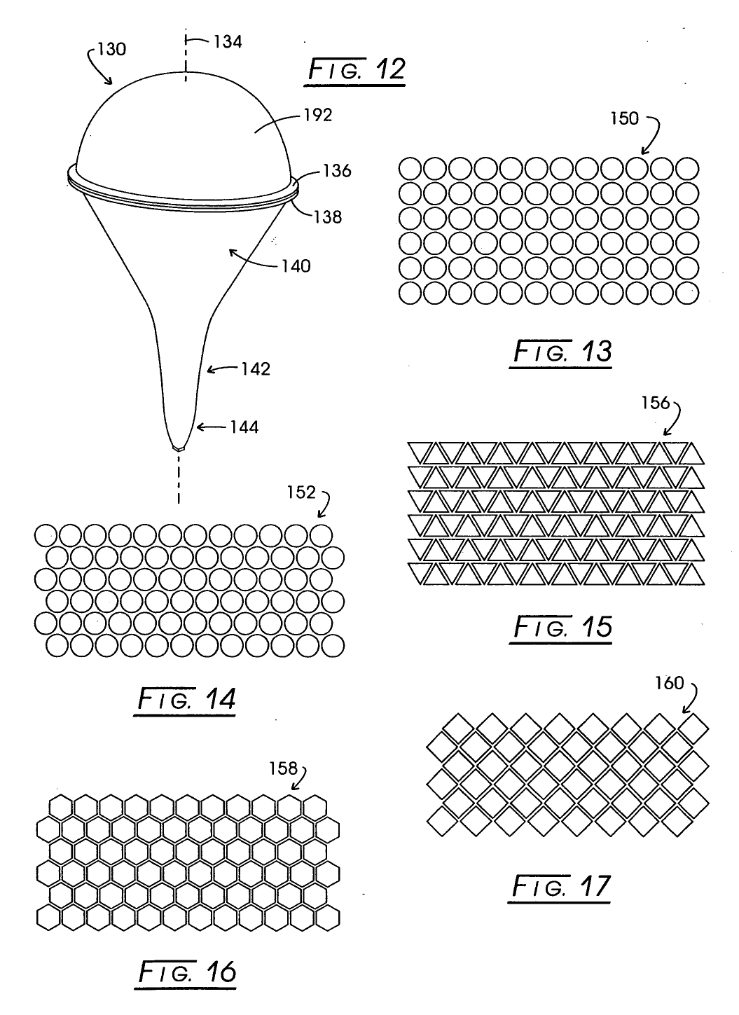

Looking to the geometric arrangement of such hemispherical lenses as at 132 within a panel array, different configurations may be contemplated. Looking to FIG. 13 an array as represented generally at 150 is arranged in a matrix of regularly disposed rows and columns. Correspondingly, as shown in FIG. 14, an array of similarly configured optical cells are seen to be arranged with imaging lens components located in a matrix of inter-nested rows and columns. Here, the columns are slightly offset.

Where the optical components are truncated to define cross-sections representing a regular polygon, other array assemblages may be contemplated. For instance, looking to FIG. 16, an array of imaging lenses truncated with piano sides displaying a triangular cross-section may be arranged as shown at 156. Where the truncation results in hexagonal cross-sections the array of imaging lenses may appear as at 158 seen in FIG. 16. Where the square across section truncation as described in connection with FIGS. 1-10 is employed, the imaging lenses also may be organized to derive an array as at 160 in FIG. 17 wherein a multiple diamond pattern is evoked by rotating the cross-sections 45° with respect to a panel edge.

Now considering the sparse array of multifunction photovoltaic cells and the support of that array along with a collection network, reference is made to FIG. 18 where a top view is provided representing a portion of those components as mounted within a support lattice. In the figure, the support lattice 70 of back support 26 is seen to be configured with a matrix of rows and columns, certain of the rows being identified at 164 extending between lengthwise sides 16 and 18 of frame 62 as described earlier in connection with FIG. 1. Disposed normally to the rows 164 are columns, certain of which are represented at 166. Formed at the intersection of the rows 164 and columns 166 are embedded square photovoltaic cells, the active areas of which are exposed at small rectangular (square) windows and certain ones of that combination are represented in the drawing at 168. Also as described above, the serial connection of row-mounted photovoltaic cells is by discrete lengths of embedded electrically conductive (copper) foil as represented at certain locations in phantom at 170. The circuit components 170 extend within the rows to be coupled in parallel by bus bars extending between the sides 16 and 18, the outputs from which have been described at 30-33 in FIG. 1. Support lattice 70 is formed of a polyester resin, for instance, polyethylene terephthalate.

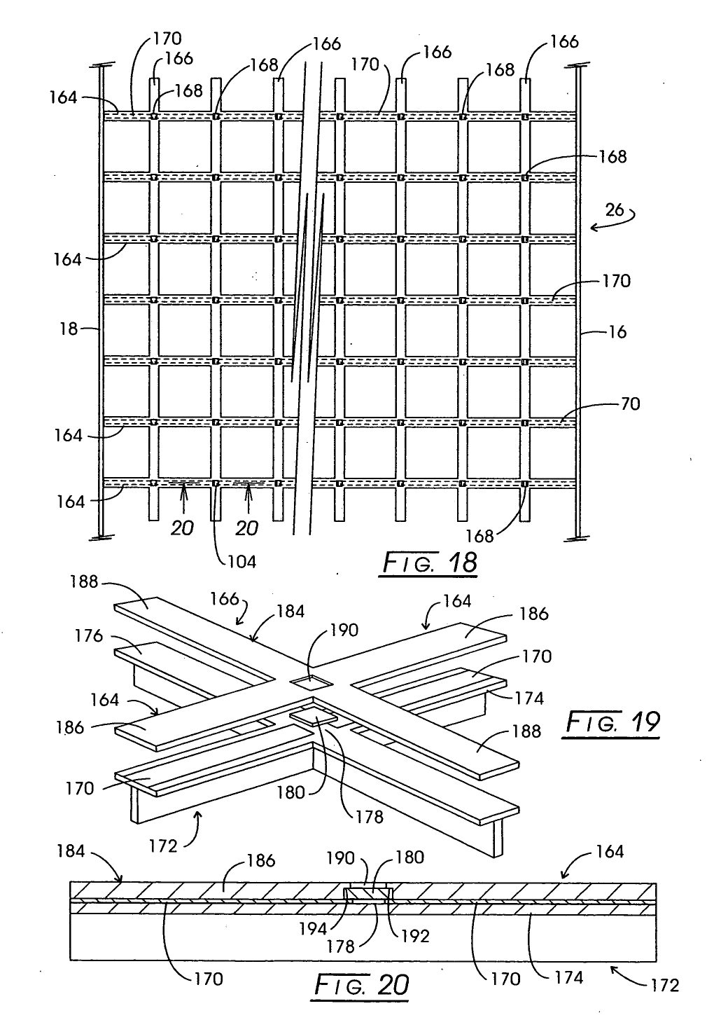

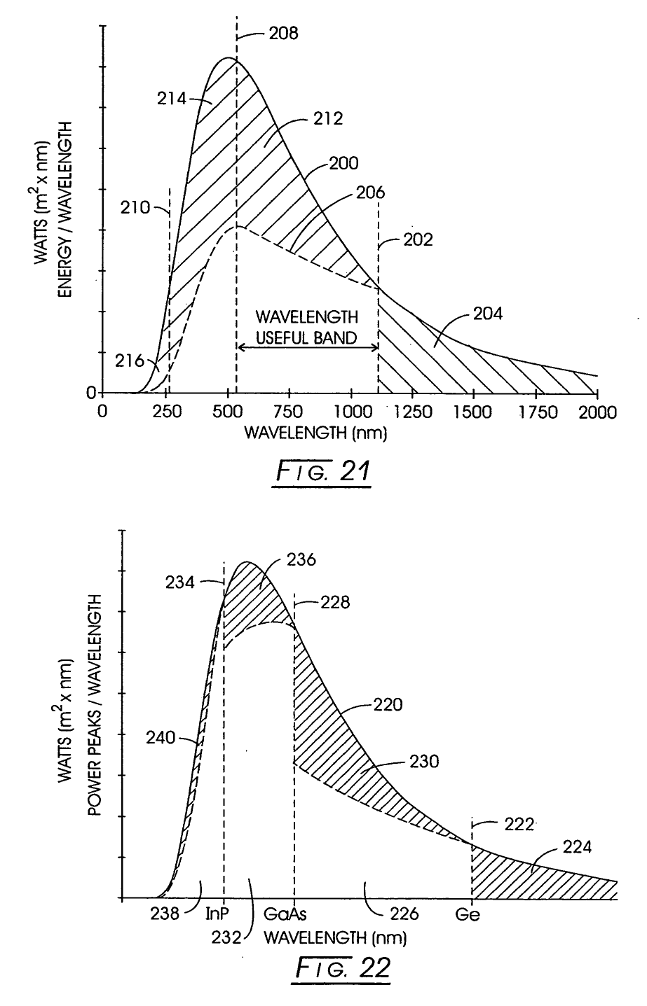

Support lattice 70, its associated collection network circuit components and photovoltaic cells is fashioned as a compound formed of two components. The lower component is provided as a structure support lattice represented generally at 172. Lattice 172 may be configured having a general “T” configuration with a downwardly extending rib component adding to its structural rigidity. Similar structural rigidity can be achieved by forming it with a channel cross-section having two spaced apart downwardly extending flanges or ribs. FIG. 19 reveals that at the intersection of a row component as at 174 of the support lattice with a column component as at 176 there is developed a support surface as at 178 located to receive the underside of a multijunction photovoltaic cell as shown at 180. Photovoltaic cell 180 is cut from a large wafer and, at the present time is square, each peripheral side thereof being two millimeters in extent. The top surface of the photovoltaic cell has an active surface which is square having peripheral sides of 1.5 mm length. That provides a 0.5 mm border around the active area. The bottom of the photovoltaic cell 180 is configured with oppositely disposed electrical contacts or pads which provide its photovoltaic output in response to radiation. Where the multijunction photovoltaic cell 180 is of a silicon variety, then the active surface is coated with silicon nitrite. The electrical contacts at opposite edges of the photovoltaic cells as at 180 are positioned in circuit completing abutment with copper foil circuit components of the collection network as again identified at 170. This abutting association is illustrated in exaggerated fashion in FIG. 20.

The second component of the back support 26 is an overlay lattice formed of the same polyester material having row components as at 186 and column components as at 188. At the intersection of the components 186 and 188 there is a rectangular window opening 190 which is configured as a square having sides of 1.5 mm length. The outwardly disposed underside border of the window defines a compressing surface 192 for retaining photovoltaic cell 180 in position while exposing its active area. A square inset surface 194 is seen to surround the sides of photovoltaic cell 180. In fabrication, the overlay lattice 184 is fused to the support lattice 172, for example, employing ultrasonic welding.

With the thus identified geometry the exposed active surface of the photovoltaic cell 180 exhibits an area of 2.25 square millimeters. Correspondingly, the exit plane as at 94 (FIG. 10) exhibits an area of 645.16 millimeters square. This provides an area-based concentration ratio of about 286.74:1. That concentration ratio can be expanded by the simple expedient of lowering the open area at window 190. Also, the area-defining size photovoltaic cells as at 180 can be reduced. However, as the size is reduced to improve the geometric concentration ratio, alignment considerations in the course of fabrication of the panel become the subject of study. In general a geometric concentration ratio of about 100:1 or higher will provide acceptable panel performance.

The preferred liquid for the optical cells is water such that these cells comprise a water hemisphere; a water cone; a water logarithmic “trumpet” and a water compound parabola. The combined secondary concentrators are referred to as a “horn” In general, a “pure” water is employed. However, as a practical matter no water, naturally occurring or treated by man, consists solely of H₂O molecules. One approach to purifying water utilizes reverse osmosis as a final filtration. Seven ultra-pure water systems incorporating reverse osmosis at the point of use of the water have been engineered and manufactured by Osmonics, Inc. of Minnetonka, Minn. Combined, these systems have the capacity to produce greater than 2000 GPM of ultra-high purity “18 Megohm” water.

Two multifunction photovoltaic cells are employed with the system of the invention. One of these is a unispectral multijunction silicon cell, marketed by Photovolt, Inc. of Cleveland, Ohio, and the other is a multi-spectral multijunction cell having the solar cell structure GaImP₂/GaAs/Ge marketed by Spectrolab, Inc. of Sylamar, Calif.

The optical cells of the panels of the invention are configured to remove components of solar energy from the accepted solar radiation which correspond with those wavelengths substantially ineffective to evoke a photovoltaic output. This has been referred to as “spectral cooling”. Spectral cooling can be accomplished utilizing dichroic film or, preferably from a cost standpoint, dyes which block ineffective solar energy components (ISEC) may be employed. Additionally, these ineffective solar energy components may be shifted to become effective solar energy wavelengths through the addition of liquid additives carrying out luminescence, phosphorescence or fluorescence. Such wavelength shifting not only accomplishes spectral cooling but affords the opportunity to create more useful radiation energy.

Now considering the aspects of heat generation by a silicon multijunction photovoltaic cell, it may be observed that the sun may be considered to be a black body radiating at about 5800 degrees Kelvin (at earth). In general, radiation may be considered in terms of energy per wavelength, following the Planck curve of the emission of light. Looking to FIG. 21, such a Planck curve with respect to a silicon multifunction photovoltaic cell is schematically represented at 200. In general, the curve 200 relates electrical energy to wavelength energy following Planck's formula which may be represented as follows:
E=\overline{h}/λ
(\overline{h} is Planck's Constant divided by 2π).
   In general, the ordinate of curve 200 may be represented as energy per wavelength or watts/(m²×nm) and the abscissa represents wavelength in nanometers. Planck's formula represents that, as wavelengths become smaller, the energy in the associated photons grows greater. However, bandgap energy remains constant. It may be further observed that the circuit associated with a given photovoltaic cell can absorb bandgap energy. For silicon devices, that bandgap energy (BGE) is present at 1100 nanometers as represented by vertical dashed line 202. Accordingly, for such devices, the energy represented at longer wavelengths and illustrated in crosshatched fashion at 204 is too weak and is manifested within the photovoltaic device as heat.

On the other hand, as the wavelength shortens, photon energy increases and photons which may be absorbed in the depletion layer to contribute to electrical production will fall below internal dashed curve 206. Note that curve 206 somewhat peaks at one-half the value of wavelengths representing bandgap energy at dashed line 202. This halfway point is represented at vertical dashed line 208 which extends from 550 nanometers wavelength. Halving that wavelength again results in a 275 nanometer wavelength represented at vertical dashed line 210. As is apparent, between vertical dashed lines 208 and 210 very little useful energy is available for the generation of electrical output, photons, in effect, being transmitted through the photovoltaic device to create heat. Hatched areas 212, 214 and 216 reveal very little effective depletion layer generated energy. Accordingly, the wavelengths between bandgap energy line 202 and about one-half of the associated wavelength at line 208 is considered a band of useful wavelengths. In this regard, while that region contains non-useable photon energies as represented at hatched region 212, by restricting operation of the photovoltaic cell in effect between lines 202 and 208, a substantial amount of heat generating energy is avoided. In effect, the noted “spectral cooling” can be achieved. Through the utilization of wavelength shifting additives to the liquid of the optical cells, for instance, light energy in the infrared region may be shifted and converted to wavelengths within the useful bands.

The spectral cooling and wavelength shifting approaches may be applied to multi-spectral systems wherein multijunction photovoltaic cells are employed utilizing a combination of Periodic III-V semiconductor materials are employed to capture an expanded range of photon energies and enhance the overall efficiency of the solar conversion system. Referring to FIG. 22, a Planck curve again is represented schematically at 220. Curve 220 is associated with the earlier-noted indium phosphide-galium arsenide-germanium photovoltaic cell identified above. The germanium, (Ge) bandgap energy line is represented at dashed line 222. Low energy and heat creating photon interaction are represented at wavelengths above that at line 222 as represented by hatched area 224. On the other hand, a useful band of wavelengths may be represented at area 226 which extends to vertical dashed line 228 corresponding with an exemplary gallium arsenide photovoltaic cell component. Only that region of the curve represented at hatched portion 230 will be unused as heat generating photon energy. Note that the bandgap energy line 228 for gallium arsenide resides at the terminus of the germanium wavelength band of useful energy. The gallium arsenide band of useful energy is present at region 232 having a lower terminus at bandgap energy dashed line 234 representing the bandgap energy of an indium phosphide (InP) structured component. That energy which converts to heat within that useful bandwidth 232 is represented at hatched area 236. Finally, the wavelength band of useful photon energy for a photovoltaic cell component of indium phosphide is represented at region 238, while the corresponding region within that wavelength band generating heat is represented at hatched area 240. As before, dichroic film or dyes may be employed to derive spectral cooling for this multi-spectral photovoltaic cell. Such dyes or dichroic components reject light wavelengths of upwardly increasing values while excepting values lower than the wavelengths representing bandgap energy. Further, wavelength shifting additives may alter wavelengths, for example, within the IR region to wavelengths of useful bandgap energy.

For further information concerning wavelength shifting, see generally the following publications:
(3) Grande, et al., “The Application of Thin Film Wavelength-Shifting Coatings of Perspex to Solar Energy Collection”, J. Phys. D: Appl. Phys. 16 2525-2535 (1983).
(4) Myersu, “Molecular Electronic Spectral Broadening in Liquids and Glasses”, Annual Review of Physical Chemistry, Vol. 49: 267-295 (1998).

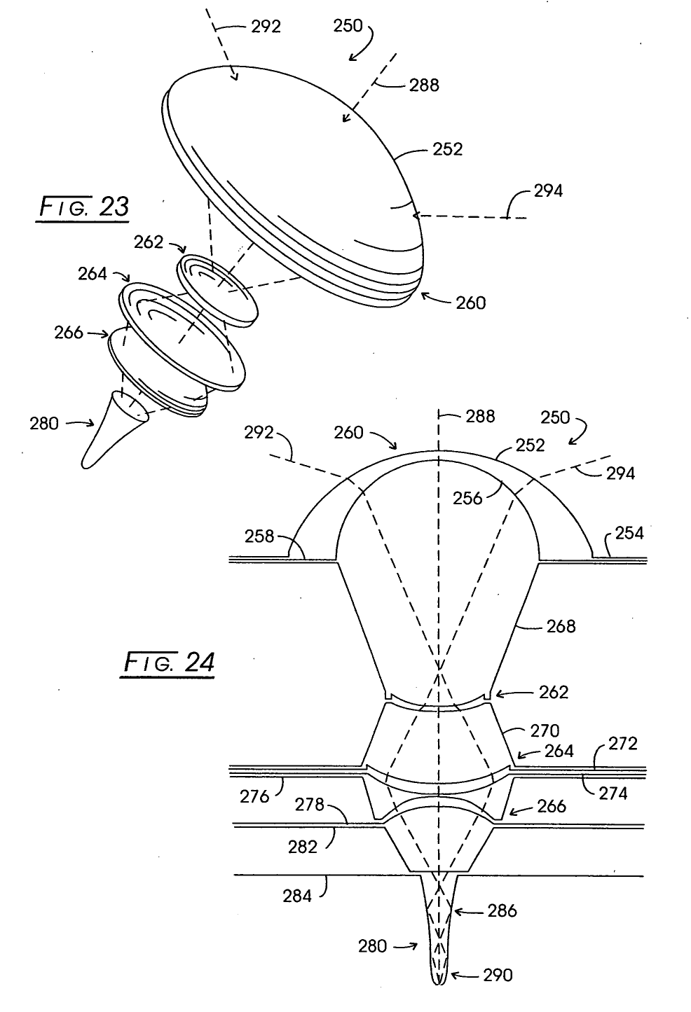

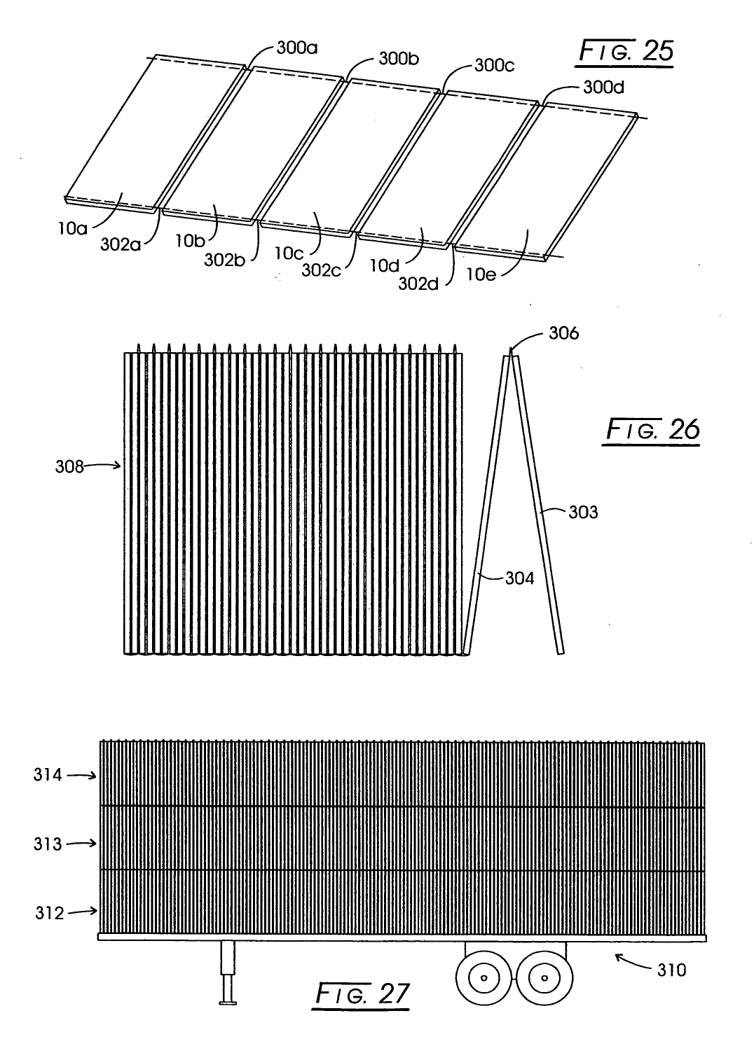

The liquid-filled thin polymeric shell lenses employed within the panel arrays may assume more optically sophisticated configurations. Such structures may, as before, be formed from very thin polyester resin sheets which are water filled and sealed by ultrasonic welding to define a water lens or concentrator. Referring to FIGS. 23 and 24, one such optical cell structure is illustrated generally at 250. FIG. 24 is slightly exploded to reveal the thin thermoplastic resin sheets within which the optical shells are formed. Cell 250 is structured as a superconcentrator combining a fish-eye imaging lens of wide acceptance angle or field of view with lenses for correcting chromatic aberration which are located in space and direct solar radiation into a logarithmic concentrator. That logarithmic concentrator, in turn, directs homogenized radiation into a compound parabolic concentrator. In the figure, the imaging fish-eye lens is shown having a hemispherical outer shell 252 formed within a thin polymeric sheet seen in FIG. 24 at 254. Outer shell 252 is combined with an inner thin shell seen in FIG. 24 at 256. Shell 256 is formed within thin polymeric sheet 258. Thus configured, the cavity between shell components 252 and 256 defines a liquid retained or water concavo-convex shaped imagining lens represented generally at 260. The concavo-convex architecture permits development of a wider acceptance angle, i.e., about 120° to provide a field of view of about 240°. Also, there is apparent weight savings in terms of the volume of water utilized to create the lens. Positioned in space below fish-eye lens 260 are three chromatic aberration correcting lenses represented generally at 262, 264 and 266. Correcting lens 262 is configured from thin polymeric sheets 268 and 270 which are formed to define a cavity providing a diverging convexo-concave lens. Similarly, correcting lens 264 is formed from thin polymeric sheets 272 and 274 to provide a concavo-convex water-based converging lens. Lens 266 is configured from thin polymeric sheets 276 and 278 to provide a converging concavo-convex water lens. Lens 266 focuses radiation to an image plane at the entrance of a non-imaging, totally internally reflective secondary concentrator represented generally at 280. Concentrator 280 is a water cell formed of thin polymeric sheets 282 and 284 and is configured with a logarithmic concentrator component represented generally at 286, the entrance of which is located to receive radiation from the image plane developed from lens 266 and extends along the cell axis represented at ray trace 288 logarithmically approaching it to an exit. Commencing from that exit is a compound parabolic concentrator represented generally at 290 which receives radiation from the logarithmic concentrator 286 exit and concentrates it at an exit plane. Additional ray traces are represented at dashed lines 292 and 294.

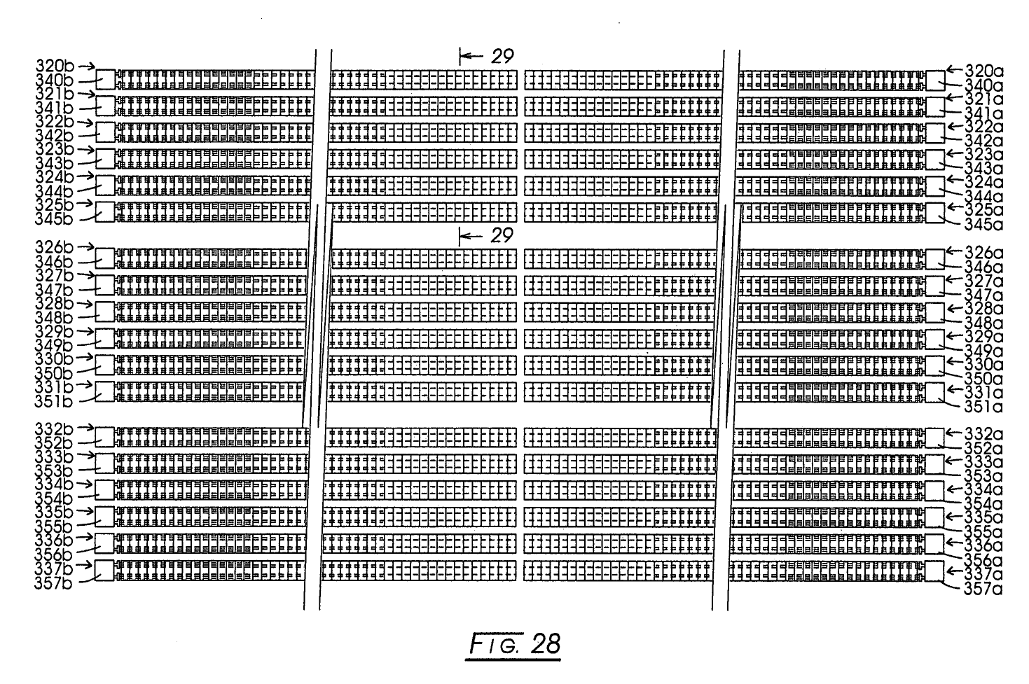

Panels as at 10 are intended to be both physically and electrically interconnected in panel arrays suited for positioning upon terrain, for example, reclaimed mining surfaces. The number of such panel arrays is quite extensive, thousands of square miles of panel supporting terrain being contemplated. Thus, as demonstrated above, the panels are relatively inexpensive and of low weight. To minimize the cost of their installation over terrain, the panels are interconnected physically and electrically at the site of their manufacture in arrays of 550 units. Looking to FIG. 25, a sub-array or set of panels identified at 10a-10e are interconnected at their panel outputs. Those panel outputs may be provided with robust braided electrical circuit components which establish both electrical communication and physical association of adjacent panels, however, those functions may be separate. Such interconnection is shown in the figure at dashed line components 300a-300d and 302a-302d. These interconnections extend at the ends of the arrays to array outputs. The connections as at 300a-300d and 302a-302d are flexible and join the lengthwise sides of adjacent panels in a mutually parallel and spaced relationship. Such joining also mutually aligns the end peripheries of panels of the array. The connector spacing is such that the array of panels may be Z-folded to facilitate their transportation. Looking to FIG. 26, the Z-folding is shown underway with respect to panels 303 and 304 which are joined with connectors as symbolically represented at 306. Such Z-folding provides a self-supporting compact folded array, the size of the panels being nominally 4 feet by 8 feet, 1100 of the folded panels may be mounted upon the flatbed of a truck having a length of, for example, 52 feet and a width of about 9 feet. Such a truck or transportation platform or surface can transport 1100 panels which are vertically stacked in lengths of about 52 feet. Looking to FIG. 27, a flatbed trailer is represented generally at 310 which is shown supporting three vertically stacked folded panel array components 312-314.

Looking to FIG. 28, paired arrays of 550 panels are represented at 320a, 320b-337a, 337b supported upon terrain. Each of these panel arrays comprise 550 panels with such an arrangement, combined panel arrays, for example, at 320a and 320b will extend in length about one mile. Within each array of 550 panels, the panels are electrically interconnected in sequences or sets of ten panels. Thus, the combined 55 electrically associated panel sequences will derive an array output constituted as 55 paired (plus and minus) panel array outputs. This sub-combination of panel array electrical connections is represented in FIG. 28 symbolically by small dashed marks located adjacent the lengthwise sides of the panels. In one embodiment of the invention the array outputs for each 550 panels are directed to an assemblage of storage battery cells. For both performance and cost purposes it is preferred that those storage battery cells be of a sodium sulphur variety. Such assemblages of battery cells are represented in the figure at blocks 340a, 340b-357a, 357b. From these storage battery facilities, the d.c. power may be transmitted by a d.c. transmission system to a user facility or initial treatment facility intended to provide a value added feature to this power. High voltage d.c. transmission systems are considered more efficient than corresponding a.c. transmission systems. Such d.c. transmission systems are available from Asea Boveri and Brown (ABB) of Switzerland.

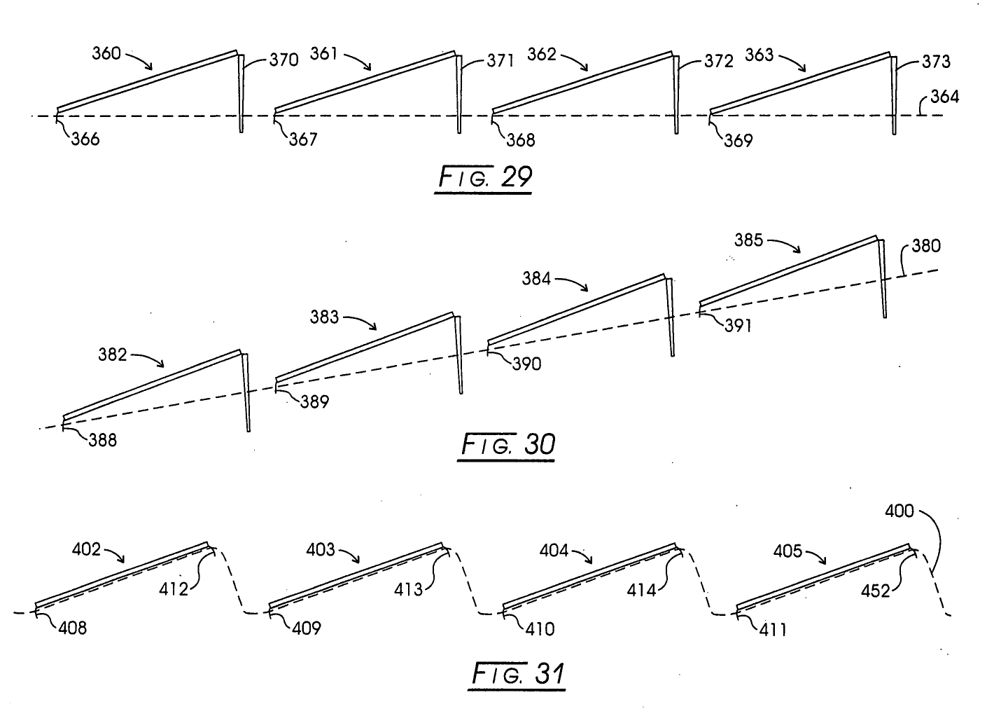

Current land regions considered for implementing the system of the invention are, for instance, recovered surface mine land in the western regions of the United States or so called “brown fields” in Midwestern regions of the United States. Where the extensive arrays of panels are employed, considerations are made for rain runoff to avoid leaching phenomena or the like. It is further desirable that the amount of on-site labor involved in mounting the panels on ground surface be minimized. Accordingly, as described in connection with FIG. 1, each panel is configured with oppositely disposed inwardly bendable ground engaging flanges earlier-described at 36 and 38. These flanges are intended to accommodate different terrain contours, for example, looking to FIG. 29, panels 360-363 are seen mounted upon a ground surface represented as dashed line 364. For the mounting, the ground engaging flanges 366-369 are, in effect, “planted” a slight distance beneath the surface 364. The slope of the active upper surfaces of the panels is developed by downwardly bending and longitudinally structurally bending the oppositely disposed ground engageable legs as described in FIG. 1 at 48 and 50. Accordingly for the flat terrain shown in FIG. 29 at dashed line 364, these legs, one of which is shown at 370-373 for respective panels 360-363 are slightly buried beneath the ground surface 364 to provide a desired uniform panel face slope.

Looking to FIG. 30, a ground surface which is sloping is represented at dashed line 380. A sequence of panels are represented in general at 382-385. The ground engaging flanges 388-391 of respective panels 382-385 penetrate ground surface 380 a relatively small amount. Correspondingly, the downwardly bent legs, one of which is represented at 394-397 at respective panels 382-385 are buried beneath surface 380 to a lesser extent than corresponding legs 370-373 shown in FIG. 29.

For some installation sites, it may be found practical to contour sloping terraces into ground surface. Looking to FIG. 31, the ground surface of such sloping terraces is represented at dashed line 400. Over these sloping surfaces are mounted panels 402-405. For this form of mounting, the ground surface itself provides the appropriate panel active area slope. Accordingly, the flanges 408-411 of respective panels 402-405 are bent downwardly and embedded below surface 400 as before. However, the opposite sequence of flanges as at 412-415 also are downwardly bent and embedded below the ground surface 400. In this regard, the legs are not deployed.

A wide variety of uses of the somewhat extensive amount of direct current power produced by the instant system can be contemplated, for instance, supplementing the power grids in existence; providing direct current inputs to industrial facilities such as bauxite smelters; and of particular interest in generating inexpensive hydrogen.

Preliminary computations with the instant system are indicating a cost per peak watt of $0.04. Sunlight illuminates most regions of the earth between 1200-2400 hours per year. Thus, each watt produces between 1.2 to 2.4 kWh per year. With a twenty-year life span and normal discount rates a payment of $0.03 per year is needed to support each watt. This translates to $0.0025 and $0.00125 per kWh produced. Electricity in the United States sells generally at an average retail price in excess of $0.08 per kWh.

The direct current generated by the panel arrays may be used to decompose water into hydrogen and oxygen. This requires 50 kWh per kg of hydrogen. At a cost of $0.0025 and $0.00125 per kWh, this implies an electrical cost of $0.125 and $0.0625 per kg of hydrogen. That represents a price ranging from $125.00 per metric ton of hydrogen in areas such as Pennsylvania and $62.50 per metric ton in areas such as Nevada. The costs of the equipment and water needed add little to such costs.

A ton of hydrogen can be used to directly hydrogenate ten tons of coal into sixty barrels of oil. Since a ton of coal can be acquired at, for example, a mine site in Wyoming at less than $6.00, $60.00 is added to the overall cost. Thus, synthetic oil can be produced at $2.10 per barrel recurring cost. When the cost of the reactors, transmission lines and all other costs are added, the system can form the basis of producing synthetic oil for about $9.00 per barrel. Direct hydrogenation of coal to oil was first achieved by Fredrich Bergius in 1913. Heretofore, the cost of hydrogen has kept this process from being used commercially. Where the system is located, for instance, in Nevada, each square mile of land is estimated to yield over 1,200,000,000 kWh of energy. Thus each square mile of land in Nevada may produce enough electricity to make 24,000 tons of hydrogen per year. This is enough hydrogen to hydrogenate 240,000 tons of coal to produce 1.44 million barrels of oil per year. About 3,000 square miles of reclaimed surface mining land will be sufficient to produce about 4.4 billion barrels of synthetic oil per year which approximates all of the oil imported yearly by the United States at the current time.

Of course, transitioning from a coal and petroleum-based power consuming populace to a hydrogen-based power consuming populace would promise substantial ecological advantages.

Since certain changes may be made in the above system and apparatus without departing from the scope of the invention herein involved, it is intended that all matter contained in the above-description or shown in the accompanying drawings shall be interpreted as illustrative and not in a limiting sense.

1. A system for deriving an electrical output from radiation of the sun comprising:
an array of solar radiation responsive cells each disposed about a cell axis and having an outwardly disposed primary concentrator configured as a thin polymeric shell retaining a liquid defining an imaging lens performing in conjunction with adjacent primary concentrators to derive a field of view effective to substantially track said solar radiation and effect an imaging thereof along a concentration light path toward an image plane, a secondary concentrator configured as a thin polymeric shell retaining a liquid with a receiving portion located to receive solar radiation from said image plane and inwardly tapering to effect a non-imagining internal reflection of received solar radiation deriving homogenized solar radiation of generally uniform intensity, and a multifunction photovoltaic cell having a receiving side located for photovoltaic interaction with said homogenized solar radiation and in heat transfer relationship with said liquid and responsive to radiation impinging upon said receiving side to derive a cell electrical output; and
a cell array network coupled with each said cell electrical output and having one or more array electrical outputs.

2. The system of claim 1 in which:
said primary concentrators perform to derive a field of view of about 120°.

3. The system of claim 1 in which:
said polymeric shells are formed of a polyester resin.

4. The system of claim 3 in which:
said polymeric shells are formed of polyethylene terephthalate.

5. The system of claim 4 in which said polymeric shells exhibit a thickness of about 150 microns to about 200 microns.

6. The system of claim 1 in which:
said liquid comprises water.

7. The system of claim 1 in which:
each said radiation responsive cell is configured to remove components of solar energy from said concentration light path corresponding with at least a portion of those wavelengths substantially ineffective to evoke said cell electrical output.

8. The system of claim 1 in which:
said primary concentrator polymeric shell and said secondary concentrator polymeric shell are coupled together to retain a common said liquid.

9. The system of claim 1 in which:
said multijunction photovoltaic cell is dimensioned having a receiving side area of that small value effective to maintain a working temperature within said liquid between about 100° C. and about 125° C.

10. The system of claim 1 in which:
at least a portion of said non-imagining secondary concentrator polymeric shell is configured with a generally logarithmic profile symmetrically disposed about said cell axis.

11. The system of claim 1 in which said secondary concentrator comprises:
a logarithmic concentrator having a said liquid retaining polymeric shell being configured with a generally logarithmic profile extending from said receiving portion to an exit aperture; and
a compound parabolic concentrator extending from said exit aperture to a tip, said liquid retaining polymeric shell thereof being configured with a profile effective to present said homogenized light at an exit plane.

12. The system of claim 11 in which:
said receiving side of said multijunction photovoltaic cell is generally located at said exit plane.

13. The system of claim 11 in which:
said liquid retaining polymeric shell of said compound parabolic concentrator is integrally formed with said liquid retaining polymeric shell of said logarithmic concentrator.

14. The system of claim 13 in which:
said liquid retaining polymeric shell of said primary concentrator is coupled in liquid retaining relationship with said liquid retaining polymeric shell of said logarithmic concentrator.

15. The system of claim 1 further comprising:
a generally flat back support extensible along ground surface configured to support said array of solar radiation responsive cells in stationary fashion.

16. The system of claim 15 in which said back support further comprises:
an electrically insulative support lattice having an array of support surfaces configured to receive and locate a said photovoltaic cell for said interaction with said homogenized radiation, and further configured for supporting said array network.

17. The system of claim 16 in which:
said back support further comprises a frame of generally rectangular configuration supporting said support lattice.

18. The system of claim 17 in which:
said back support is formed of a polymeric material.

19. The system of claim 18 in which:
said back support polymeric material is a polyester resin.

20. The system of claim 18 in which:
each said solar radiation cell exhibits a height of about 2¾ inches;
each said primary concentrator exhibits an exit area of about 645 square millimeters;
said liquid comprises water; and
each said photovoltaic cell receiving side exhibits an area of about 2.25 square millimeters.

21. The system of claim 1 in which:
each said primary concentrator is configured with an outwardly disposed polymeric sheet component having a generally convex lens external profile and an inwardly disposed generally concave polymeric sheet component sealably fixed to the underside of said outwardly disposed polymeric sheet component to provide a cavity therebetween retaining said liquid to define a concavo-convex shaped imaging lens.

22. The system of claim 21 in which said primary concentrator further comprises an assemblage of one or more correction lenses effective to provide correction for chromatic aberration at said image plane, each said correction lens being configured with a first polymeric sheet component having a generally convex lens profile and a second polymeric sheet component sealably fixed to one side of said first polymeric sheet component to provide a cavity therebetween retaining said liquid to define a correction lens.

23. The system of claim 21 in which said secondary concentrator is configured as a molded discrete polymeric sheet component at least a portion thereof having a generally logarithmic profile and defining a homogenization cavity retaining said liquid.

24. The system of claim 23 in which:
said secondary concentrator logarithmic profile extends from said receiving portion to an exit and further comprises:
an integrally formed compound parabolic concentrator extending from said exit, said discrete polymeric sheet component extending from said exit to a tip, said polymeric sheet component being configured with a generally parabolic profile effective to focus said homogenized light at an exit plain located adjacent said tip and defining a cavity retaining said liquid in common with said cavity of logarithmic profile.

25. The system of claim 1 in which:
said primary concentrator imaging lens is of generally hemispherical shape disposed about a cell axis and extending to an imaging lens exit area.

26. The system of claim 25 in which said secondary concentrator is symmetrically disposed about said cell axis and comprises:
a logarithmic concentrator having an entrance configured and located for receiving radiation at said image plane and having one or more surfaces extending from said entrance logarithmically approaching said cell axis to an exit; and
a compound parabolic concentrator having one or more surfaces located for receiving radiation from said logarithmic concentrator exit and concentrating it at said photovoltaic cell receiving side.

27. The system of claim 25 in which said secondary concentrator further comprises:
a conical concentrator having an entrance adjacent said imaging lens exit area and an exit adjacent said image plane and having one or more side surfaces inclined toward said cell axis.

28. The system of claim 27 in which:
said primary and secondary concentrators are configured to retain a common said liquid.

29. A system for deriving an electrical output from radiation of the sun, comprising:
one or more arrays of panels supported over a ground surface between oppositely disposed panel array ends;
each said panel having an array of solar radiation responsive cells, each comprising:
a generally upwardly disposed primary concentrator configured with one or more liquid retaining polymeric surfaces defining an imaging lens performing in conjunction with adjacent primary concentrators to derive a field of view of extent effective to receive solar radiation extending toward said panels throughout a substantial portion of a daytime defined interval of said radiation and to effect an imaging thereof toward an imaging plane, a secondary concentrator configured with one or more liquid retaining polymeric surfaces with a receiving side located to receive solar radiation from an imaging lens and inwardly tapering to effect a non-imaging internal reflection of received solar radiation deriving homogenized solar radiation of generally uniform intensity, and a multijunction photovoltaic cell having a receiving side located for photovoltaic interaction with said homogenized solar radiation and in heat transfer relationship with said liquid and responsive to radiation impinging upon said receiving side to derive a cell electrical output;
each said panel further comprising:
a generally flat back support supported over said ground surface having an outwardly disposed frame structure configured to support said array of solar radiation cells in stationary fashion and said back support supporting a cell array network coupled with each said cell electrical output and having one or more panel outputs;
said panel outputs of each said array of panels being electrically interconnected to derive one or more panel array outputs at one or more panel array end locations; and
one or more storage cell assemblies coupled in charging relationship with a said panel array output.

30. The system of claim 29 in which:
said one or more storage cell assemblies are sodium-sulfur storage cell assemblies.

31. The system of claim 29 in which:
each said solar radiation responsive cell is configured to remove components of solar energy corresponding with at least a portion of those wavelengths substantially ineffective to evoke said cell electrical output.

32. The system of claim 29 in which:
each said solar radiation responsive cell is configured to shift at least a portion of ineffective solar energy components of solar radiation of said solar radiation to one or more wavelengths effective to evoke said cell electrical output.

33. The system of claim 29 in which:
each said solar radiation responsive cell retained liquid comprises one or more wavelength shifting additives effective to shift at least a portion of ineffective solar energy components of said solar radiation to one or more wavelengths effective to evoke said cell electrical output.

34. The system of claim 29 in which:
said liquid retained by said primary and secondary concentrators comprises one or more wavelength absorbing additives effective to absorb solar energy from at least a portion of said solar radiation substantially ineffective to evoke a cell electrical output.

35. The system of claim 31 in which:
said multijunction photovoltaic cell is dimensioned having a receiving side area of that small value effective to maintain a working temperature within said liquid between about 100° C. and about 125° C.

36. The system of claim 35 in which:
each said photovoltaic cell receiving side exhibits an area of about 2.25 square millimeters.

37. The system of claim 29 in which said secondary concentrator comprises:
a logarithmic component configured with a generally logarithmic profile extending about a cell axis from said imaging plane to a logarithmic concentrator exit; and
a compound parabolic component extending from said logarithmic concentrator exit and configured with a compound parabolic profile effective to concentrate said homogenized radiation at an exit plane.

38. The system of claim 37 in which said primary concentrator is of generally hemispherical shape disposed about said cell axis and extending to an imaging lens exit area.

39. The system of claim 38 in which said secondary concentrator further comprises:
a conical concentrator having an entrance adjacent said imaging lens exit area and an exit adjacent said imaging plane and having one or more side surfaces inclined toward said cell axis.

40. The system of claim 37 in which:
said receiving side of said multijunction photovoltaic cell is located at said exit plane.

41. The system of claim 29 in which said back support further comprises:
an electrically insulative support lattice having an array of support surfaces configured to receive and locate a said photovoltaic cell for said interaction with said homogenized solar radiation, and further configured for supporting said cell array network.

42. The system of claim 29 in which:
each said solar panel exhibits a generally rectangular periphery of given length and width; and
said array of solar panels is a generally linear assemblage of solar panels.

43. Panel apparatus for deriving an electrical output from radiation of the sun, comprising:
a generally stationary array of optical cells each having an outwardly disposed imaging lens component disposed about a cell axis, performing in conjunction with adjacent imaging lens components to derive a field of view effective for accepting solar radiation during a substantial portion of a day, exhibiting an imaging lens exit area and generally imaging accepted radiation to an image plane, and one or more non-imaging internally reflecting concentrator components receiving radiation from said image plane at a non-imaging region entrance and concentrating it to an exit plane exhibiting a concentration area substantially less than said exit area to define a concentration ratio;
an array of discreet multijunction photovoltaic cells each having an active receiving surface of area extent generally corresponding with said concentration area, located substantially at said exit plane and having a photovoltaic output in response to radiation at said exit plane; and
a collection network with circuit components receiving each said photovoltaic output and providing one or more panel outputs.

44. The panel apparatus of claim 43 in which:
said concentration ratio is at least about 100:1.

45. The panel apparatus of claim 43 in which:
said non-imaging concentrator components are symmetrically disposed about said cell axis and comprise:
a logarithmic concentrator having an entrance configured and located for receiving radiation at said image plane and having one or more surfaces extending from said entrance logarithmically approaching said cell axis to an exit; and
a compound parabolic concentrator having one or more surfaces located for receiving radiation from said logarithmic concentrator exit and concentrating it at said exit plane.

46. The panel apparatus of claim 45 in which:
said non-imaging concentrator components further comprise:
a conical concentrator having an entrance adjacent said imaging lens exit and an exit adjacent said image plane and having one or more side surfaces inclined toward said cell axis.

47. The panel apparatus of claim 43 in which:
said imaging lens component is configured as a polymeric surface retaining a liquid.

48. The panel apparatus of claim 43 in which:
said non-imaging concentrator components are configured as a polymeric surface retaining a liquid.

49. The panel apparatus of claim 48 in which:
each said photovoltaic cell receiving surface is immersed in thermal exchange relationship with said liquid retained within said polymeric surface.

50. The panel apparatus of claim 43 in which:
said non-imaging concentrator components are configured to provide said radiation at said exit plane as homogenized radiation substantially exhibiting a Lambertion distribution across an associated said photovoltaic cell active receiving surface.

51. The panel apparatus of claim 43 in which:
said imaging lens component and said non-imaging concentrator components are configured with polymeric surfaces surmounting a common liquid-filled cavity.

52. The panel apparatus of claim 51 in which:
said polymeric surfaces are formed of a polyester resin.

53. The panel apparatus of claim 52 in which said liquid is under a pressure effective to place said polymeric surfaces in tension.

54. The panel apparatus of claim 52 in which:
said polymeric surfaces exhibit a thickness of about 150 microns to about 200 microns.

55. The panel apparatus of claim 52 in which:
said polymeric surfaces are formed of polyethylene terephthalate.

56. The panel apparatus of claim 43 in which:
each said optical cell is configured to remove components of solar energy from said solar radiation corresponding with at least a portion of those wavelengths substantially ineffective to evoke said photovoltaic output.

57. The panel apparatus of claim 56 in which:
said imaging lens components and said non-imaging concentrator components are configured as polymeric surfaces retaining a common liquid;
said liquid comprising one or more wavelength absorbing additives effective to absorb solar energy from at least a portion of those wavelengths of said solar radiation substantially ineffective to evoke said photovoltaic output.

58. The panel apparatus of claim 56 in which:
said imaging lens components and said non-imaging concentrator components are configured as polymeric surfaces retaining a common liquid; and
said liquid comprises one or more wavelength shifting additives effective to shift at least a portion of ineffective solar energy components of said solar radiation to one or more wavelengths effective to evoke said photovoltaic output.

59. The panel apparatus of claim 43 in which:
each said imaging lens component is a generally hemispherical lens having an effective thickness extending along said cell axis to an exit plane defining said exit area; and
each said imaging lens component within said array being located in close adjacency with each next imaging lens component within said array.

60. The panel-like apparatus of claim 59 in which:
each said imaging lens component is configured with a peripheral surface generally parallel with said axis extending from said exit plane a distance less than said thickness and exhibiting a cross section enhancing said location of close adjacency or commonality with each next imaging component within said array.

61. The panel apparatus of claim 60 in which:
each said non-imaging entrance has a cross-section corresponding with said imaging lens component peripheral surface cross-section.

62. The panel apparatus of claim 60 in which:
said cross-section is generally a circle.

63. The panel apparatus of claim 62 in which:
said array of optical cells is configured with said imaging lens components arranged in a matrix of regular rows and columns.

64. The panel apparatus of claim 62 in which:
said array of optical cells is configured with said imaging lens components arranged in a matrix of internested rows and columns.

65. The panel apparatus of claim 60 in which:
said imaging lens component peripheral surface cross-section is substantially square; and
each said multijunction photovoltaic cell receiving surface exhibits a substantially square periphery.

66. The panel apparatus of claim 43 in which:
each said imaging lens component is a generally hemispherical lens having an effective thickness extending along said cell axis to an exit plane defining said exit area; and
each said imaging lens component is configured with a peripheral surface generally parallel with said axis, extending from said exit plane a distance less than said effective thickness and exhibiting a regular polygon cross-section.

67. The panel apparatus of claim 66 in which:
said regular polygon is a square.

68. The panel apparatus of claim 66 in which:
said regular polygon is a triangle.

69. The panel apparatus of claim 66 in which:
said regular polygon is a hexagon.

70. The panel apparatus of claim 43 in which:
said panel apparatus exhibits a generally rectangular periphery having a length of about eight feet and a width of about four feet.

71. The panel apparatus of claim 70 in which:
said array of optical cells is configured with said imaging lens components arranged in a matrix of rows and columns; and
said collection network circuit components interconnect said photovoltaic outputs in series circuit fashion along each said row to provide oppositely disposed row outputs and said row outputs are electrically combined in parallel circuit fashion to derive said panel outputs.

72. The panel apparatus of claim 43 in which:
said panel apparatus exhibits a generally rectangular periphery;
said array of optical cells is configured with said imaging lens components arranged in a matrix of rows and columns; and
said collection network circuit components interconnect said photovoltaic outputs in series circuit fashion along each said row to provide oppositely disposed row outputs and said row outputs are electrically combined in parallel circuit fashion to derive said panel outputs.

73. The panel apparatus of claim 72 in which:
each of said photovoltaic cells exhibits a generally rectangular periphery having a rectangular upper edge border generally surrounding said receiving surface and an oppositely disposed mounting surface and having oppositely disposed electrical contact surfaces providing said photovoltaic output;
said collection network comprises a generally rectangular back support having an electrically insulative support lattice generally configured with row and column components geometrically corresponding in offset fashion with said array of optical cell image component matrix of rows and columns, said row and column components combining to derive an array of support surfaces each configured to abuttably receive the said mounting surface of a photovoltaic cell, said row components supporting electrical conductors extending in electrical communication between the electrical contact surfaces of adjacent photovoltaic cells, and an electrically insulative overlay lattice generally configured with row and column components positioned over and fixed to said support lattice and configured with rectangular window openings each having a border region mountably engaging the said edge border of a said photovoltaic cell while providing light transfer communication with a said exit plane.

74. The system of claim 73 in which:
said back support further comprises a thermoplastic resin frame of generally rectangular configuration supporting said support lattice and said array of optical cells and having oppositely disposed end periphery portions.

75. The panel apparatus of claim 74 in which:
said back support frame is configured having oppositely disposed first and second inwardly bendable ground engaging flanges extending oppositely outwardly from the end periphery portions of said frame.

76. The panel apparatus of claim 75 in which:
said first inwardly bendable ground engaging flange is configured with optionally deployable spaced apart ground engageable legs effective, when deployed by downward bending to effect a sloping of said array of optical cells.

77. A system for deriving an electrical output from radiation of the sun, comprising:
one or more arrays of panels supported in substantially stationary fashion from a ground surface;
each said panel of said one or more arrays of panels comprising an array of superconcentrator optical cells each having an outwardly facing imaging lens component disposed about a cell axis, performing in conjunction with adjacent imaging lens components to exhibit a field of view effective for accepting solar radiation during a substantial portion of a day, exhibiting an imaging lens exit area and generally imaging accepted radiation to an image plane, and one or more, non-imaging, internally reflecting concentrator components receiving radiation from said image plane, effecting its homogenization and concentrating it to an exit plane exhibiting a concentration area substantially less than said imaging lens exit area to define a concentration ratio;
each said panel having a corresponding array of discrete multijunction photovoltaic cells each such cell having an active receiving surface of area extent generally corresponding with said concentration area, located substantially at said exit plane to define a sparse photovoltaic cell array and each having a photovoltaic cell output in response to radiation at said exit plane;
each said panel having a panel collection network with circuit components receiving each said photovoltaic cell output and providing one or more panel outputs; and
said panel outputs within said array of panels being combined to provide one or more array outputs.

78. The system of claim 77 in which:
said concentration ratio is greater than about 100:1.

79. The system of claim 77 in which:
each said imaging lens component is configured as a thin polymeric shell retaining a liquid;
each said concentrator component is configured as a thin polymeric shell retaining a liquid;
each said panel exhibits a generally rectangular periphery having two oppositely disposed width defining end peripheries and two oppositely disposed lengthwise sides;
said array of optical cells and associated said array of photovoltaic cells are mounted in a matrix array of columns generally parallel with said end peripheries and rows generally parallel with lengthwise said sides; and
said panel collection network circuit components electrically couple said photovoltaic outputs in series circuit fashion along each row and electrically connect such row defined series coupled outputs in parallel circuit fashion such that said panel outputs extend at locations generally adjacent said end peripheries and two oppositely disposed lengthwise sides.

80. The system of claim 78 in which:
each said panel exhibits a said lengthwise side which is of greater extent than a said end periphery.

81. The system of claim 80 in which:
each said panel exhibits a said lengthwise side with a length of about eight feet and a said end periphery with a length of about four feet.

82. The system of claim 79 in which:
said panels within an array of panels being arranged such that the lengthwise sides of adjacent panels are generally mutually parallel and said end peripheries are mutually aligned; and
adjacent said panels within said array of panels being spaced apart at said lengthwise sides and pivotally interconnected in a joining configuration effective to carry out the Z-folding of a said array of panels to facilitate the transportation thereof.

83. The system of claim 82 in which:
said adjacent panels within an array are mutually electrically interconnected at said panel outputs with flexible electrical cabling effective to derive said pivotal interconnection.

84. The system of claim 83 in which:
said flexible electrical cabling is electrically conductive braided cable.

85. The system of claim 82 in which:
each said panel lengthwise side is about eight feet in length, and each said end periphery is about four feet in length.

86. The system of claim 82 in which:
each said panel within a said array of panels further comprises a generally rectangular panel back support configured to support said sparse photovoltaic cell array and said panel collection network.

87. The system of claim 86 in which said panel back support comprises:
an electrically insulative support lattice generally configured with row and column components corresponding with said matrix mounting of said array of photovoltaic cells, said row and column components providing an array of support surfaces each configured to support a photovoltaic cell and said panel collection network circuit components being supported at said row components, and an electrically insulative overlay lattice positioned over and fixed to said support lattice and configured with window openings providing radiation transfer communication between said photovoltaic cell active receiving surface and a corresponding said exit plane.

88. The system of claim 87 in which:
said support lattice is configured to provide heat transfer communication at least between each said photovoltaic cell active receiving surface and said liquid retained by said concentrator component.

89. The system of claim 87 in which:
said superconcentrator optical cells and said panel back support are formed of a polyester resin.

90. The system of claim 89 in which:
said polyester resin is polyethylene terephthalate.

91. The system of claim 87 in which:
said panel support is configured having oppositely disposed first and second inwardly bendable ground engaging flanges extending outwardly from said end peripheries.

92. The system of claim 91 in which:
said first inwardly bendable ground engaging flange is configured with optionally deployable spaced apart ground engageable legs effective, when deployed by downward bending to effect a sloping of said array of optical cells.

93. The system of claim 77 further comprising:
an assemblage of storage battery cells coupled in charging relationship with said array outputs and having d.c. terminals.

94. The system of claim 93 in which:
said storage battery cells are sodium sulfur cells.

95. The system of claim 93 further comprising:
a d.c. transmission system coupling said battery terminals in energy transfer relationship with an energy conversion facility.
